(19) United States
(12) Patent Application Publication
(10) Pub. No.: US 2004/0124835 A1
(43) Pub. Date: Jul. 1, 2004

(54) Miniaturized magnetic impedance sensor with an IC chip having an electrode near a magnetic impedance element

(76) Inventor: Takeshi Kimura, Kanagawa (JP)

Correspondence Address: Ivan S. Kavrukov, Esq., Cooper & Dunham LLP, 1185 Avenue of the Americas, New York, NY, 10036, US

(21) Appl. No.: 10/662,911

(22) Filed: Sep. 15, 2003

(30) Foreign Application Priority Data
Sep. 24, 2002 (JP) 2002-278175

(51) Int. Cl. G01R 33/00; G01R 33/02

(52) U.S. Cl. 324/249; 324/260

(57) ABSTRACT

An MI sensor is miniaturized while maintaining high sensitivity. At least one MI element detects an external magnetic field and outputs a sense signal. The sense signal is supplied to a rectangular IC chip. The IC chip is provided with an MI element connection electrode connected to the MI element and a switching circuit controlled by a pulse signal so as to supply a pulsed magnetizing current to the MI element through the MI element connection electrode. The MI element connection electrode is located near a side of the rectangular IC chip.

### BACKGROUND OF THE INVENTION

1. Field of the Invention

The present invention relates to magnetic impedance (MI) sensors for detecting a very small magnetic field and integrated circuit (IC) chips incorporated into the MI sensors and, more particularly, to a miniaturized MI sensor which includes an IC chip and MI elements so as to detect a direction and strength of a magnetic field by driving the MI elements.

2. Description of the Related Art

Conventionally, a magneto-resistive element having a resistance changeable by an external magnetic field has been widely used as a magnetic sensor for detecting a magnetic field. A magneto-resistive element is supplied with a DC sense current so that a change in a resistance thereof is detected as a voltage change.

On the other hand, it was found that an impedance of an amorphous wire made of a soft magnetic material changes in response to a component of an external magnetic field parallel to the amorphous wire when a radio-frequency current or a pulsed current is supplied to the amorphous wire. Such a phenomenon is referred to as a magnetic impedance effect. A magnetic field detecting element using the magnetic impedance effect is referred to as a magnetic impedance (MI) element, and a magnetic sensor using the magnetic impedance effect is referred to as a magnetic impedance (MI) sensor. The MI sensors have become used in a navigation system of an automobile as a magnetic compass since the MI sensors are more sensitive to a magnetic field than a magneto-resistive element. Further, it is expected that the MI sensors are applied to detection of a biomagnetism and a magnetic guidance system of an automobile.

In the meantime, an electronic compass has been incorporated into a portable terminal such as, for example, a portable telephone, etc. Such a portable terminal has a size corresponding to the size of one's hand. Thus, there is a problem in that it is difficult to miniaturize a portable terminal when using a drive and detection circuit formed by a conventional discrete electronic circuit and an MI sensor using an MI element.

Moreover, the MI sensor detects a magnetic-field vector by decomposing it into two axes components by two MI elements, and converts the two magnetic-field vector components into an actual magnetic field by synthesizing the vector components. Since the MI sensor uses a radio frequency or a pulse of equal to or greater than several hundreds kilohertz (kHz), a detected signal varies if a signal applied to each MI element varies, which results in a detected magnetic field different from an actual magnetic field. Moreover, when the MI sensor is miniaturized by densification, there is a problem in that a signal needed to one of the MI elements becomes a noise to the other one due to a cross-talk.

### SUMMARY OF THE INVENTION

It is a general object of the present invention to provide an improved and useful MI sensor in which the above-mentioned problems are eliminated.

A more specific object of the present invention is to provide an MI sensor which can be miniaturized while maintaining high sensitivity.

In order to achieve the above-mentioned objects, there is provided according to one aspect of the present invention an IC chip configured and arranged to be used with an MI element which detects an external magnetic field and outputs a sense signal, the IC chip having a rectangular shape and supplied with the sense signal output from the MI element, the IC chip comprising: an MI element connection electrode connected to the MI element; and a switching circuit controlled by a pulse signal so as to supply a pulsed magnetizing current to the MI element through the MI element connection electrode, wherein the MI element connection electrode is located near a side of the IC chip.

In the present invention, the phrase “near a side of the IC chip” means “on a side of a substrate which forms the IC chip” or “a position as close to a side as possible” or also means “a position on a side of the side with respect to a center of the IC chip”. (Hereinafter, the term “near” is used for the same meaning.) Since the magnetizing current is a pulsed current including high-frequency components and is a relatively large current, the wire connecting the MI element and the electrode may serve as an antenna, which emits electromagnetic waves. Thus, there is a problem in that a signal-to-noise ratio of the output signal, which is output from the IC chip and represents the magnitude of the external magnetic field, is deteriorated. By providing the MI element connection electrode in such a location, a length of the wire connecting the electrode to the MI element normally facing the side of the IC chip can be reduced, thereby suppressing emission of electromagnetic waves. Consequently, an IC chip for a sensitive MI sensor can be achieved with an excellent signal-to-noise ratio.

In the IC chip according to the present invention, the switching circuit may be located near the side to which the MI element is located.

Accordingly, for example, when the MI element connection electrode is formed on a passivation layer of the outermost layer of the IC chip, the switching circuit may be provided on the IC chip substrate under the MI element connection electrode. According to such s structure, similar to the above-mentioned relationship between the MI element and the electrode, a length of the wire connecting the electrode to the MI element can be reduced, thereby suppressing emission of electromagnetic waves.

Additionally, there is provided according to another aspect of the present invention an IC chip configured and arranged to be used with MI elements including first and second MI elements, the IC chip having a rectangular shape and supplied with a sense signal from each of the first and second MI elements, the IC chip comprising: a first MI element connection electrode connected to the first MI element; a second MI element connection electrode connected to the second MI element; a first switching circuit supplying a magnetizing current to the first MI element through the first MI element connection electrode; and a second switching circuit supplying a magnetizing current to the second MI element through the second MI element electrode, wherein the first and second switching circuits are separated from each other and located symmetrically with respect to a first diagonal line of the rectangular IC chip, the first diagonal line extending between the first and second MI elements

According to the above-mentioned invention, the wiring from the first switching circuit to the first MI element can be identical to the wiring from the second switching circuit to the second MI element. Thus, a distortion of waveform and a delay in the magnetizing current due to a parasitic resistance, a parasitic capacitance, etc., can be equalized, which prevents a variation in output timing of the output signals from the first and second MI elements. Moreover, since first and second switching circuits are separated from each other, a crosstalk between the switching circuits is suppressed. Thus, a noise to the magnetizing current can be suppressed, which results in prevention of an erroneous operation of the switching circuits.

In the above-mentioned invention, the first and second switching circuits may be located on a second diagonal line different from the first diagonal line. Accordingly, a long distance can be provided between the first and second switching circuits. Thus, a crosstalk between the switching circuits is suppressed, and a noise to the magnetizing current can be suppressed, which results in prevention of an erroneous operation of the switching circuits.

The IC chip according to the present invention may further comprise first and second pulse-signal generation circuits which generate pulse signals for controlling the first and second switching circuits, respectively, wherein the pulse-signal generation circuits may be located at equal distances from the respective first and second switching circuits. Accordingly., the wiring from the pulse-signal generation circuit to each of the first and second switching circuits can be identical to each other. Thus, a variation in output timing of the magnetizing current from the first and second switching circuits can be equalized, which results in stable processing of the sense signal of the MI elements by a processing circuit of the IC chip.

The IC chip according to the present invention may further comprise a signal processing circuit which generates a detection signal corresponding to a magnitude of the external magnetic field by being supplied with the sense signals from the first and second MI elements, wherein the signal processing circuit may include a sampling circuit and located at equal distances from the first and second switching circuits. Accordingly, a variation in output timing of the sense signals induced in the MI elements can be suppressed, which permits a stable processing in the sampling circuit.

In the IC chip according to the present invention, an operational timing of the sampling circuit and an operational timing of the first and second switching circuits may be synchronized with each other. Accordingly, perks of the sense signals from the MI elements can be detected stably, which results in stable measurements of the external magnetic field.

The IC chip according to the present invention may further comprise an MI element changeover switch which switches a direction of the magnetizing current between the first and second MI elements based on a switching signal supplied from an external part, wherein the pulse-signal generation circuit may be commonly used for the first and second MI elements. Accordingly, a variation in the pulsed magnetizing current supplied to each of the MI elements with respect to time can be prevented, and a variation in the sampling timing by the signal processing circuit can be suppressed. Additionally, by sharing the pulse-signal generation circuit, a number of circuits can be reduced, which results in miniaturization of the IC chip.

Additionally, the IC chip according to the present invention may further comprise an amplifier circuit amplifying the detection signal output from the signal processing circuit, wherein the amplifier circuit may be located at a position opposite to the first and second MI element connection electrodes with respect to the second diagonal line.

Further, the IC chip according to the present invention may further comprise an output circuit which outputs the amplified detection signal supplied from the amplifier circuit, wherein the output circuit may be located at a position opposite to the first and second MI element connection electrodes with respect to the second diagonal line.

Additionally, the IC chip according to the present invention may further comprise an output electrode which outputs the detection signal supplied from the output circuit to an external part, wherein the output electrode may be located at a position opposite to the first and second MI element connection electrodes with respect to the second diagonal line.

Additionally, there is provided according to another aspect of the present invention an MI sensor comprising: an MI element detecting an external magnetic field and outputting a sense signal; and an IC chip having a rectangular shape and supplied with the sense signal output from the MI element, wherein the IC chip comprises: an MI element connection electrode connected to the MI element; and a switching circuit controlled by a pulse signal so as to supply a pulsed magnetizing current to the MI element through the MI element connection electrode, wherein the MI element connection electrode is located near a side of the IC chip.

According to the above-mentioned invention, since the magnetizing current is a pulsed current including high-frequency components and is a relatively large current, the wire connecting the MI element and the electrode may serve as an antenna, which emits electromagnetic waves. Thus, there is a problem in that a signal-to-noise ratio of the output signal, which is output from the IC chip and represents the magnitude of the external magnetic field, is deteriorated. By providing the MI element connection electrode in such a location, a length of the wire connecting the electrode to the MI element normally facing the side of the IC chip can be reduced, thereby suppressing emission of electromagnetic waves. Consequently, an IC chip for a sensitive MI sensor can be achieved with an excellent signal-to-noise ratio.

In the MI sensor according to the present invention, the switching circuit may be located near the side to which the MI element is located.

Additionally, there is provided according to another aspect of the present invention, an MI sensor comprising: a first MI element detecting an external magnetic field and outputting a sense signal; a second MI element detecting an external magnetic field and outputting a sense signal, the second MI element being positioned with a predetermined angle to said first MT element; and an IC chip having a rectangular shape and supplied with the sense signals from the first and second MI elements, wherein the IC chip comprising: a first MI element connection electrode-connected to the first MI element; a second MI element connection electrode connected to the second MI element; a first switching circuit supplying a magnetizing current to the first MI element through the first MI element connection electrode; and a second switching circuit supplying a magnetizing current to the second MI element through the second MI element connection electrode, wherein the first and second MI elements face adjacent sides of the IC chip, respectively; and the first and second switching circuits are located at identical positions with respect to the respective first and second MI elements.

In the above-mentioned invention, the first and second MI elements are positioned at the predetermined angle to each other. The predetermined angle may be any angle except for zero degree, and preferably 90 degrees. Since the first and second MI elements are positioned at a predetermined angle to each other, a direction and a magnitude of an external magnetic field can be efficiently detected.

Additionally, the wiring from the first switching circuit to the first MI element can be identical to the wiring from the second switching circuit to the second MI element. Thus, a distortion of waveform and a delay in the magnetizing current due to a parasitic resistance, a parasitic capacitance, etc., can be equalized, which prevents a variation in output timing of the output signals from the first and second MI elements. Moreover, since first and second switching circuits are separated from each other, a crosstalk between the switching circuits is suppressed. Thus, a noise to the magnetizing current can be suppressed, which results in prevention of an erroneous operation of the switching circuits. Consequently, an IC chip for a sensitive MI sensor can be achieved with an excellent signal-to-noise ratio.

Additionally, there is provided according to another aspect of the present invention an electronic equipment comprising: an MI sensor detecting an external magnetic field and outputting a detection signal; and a functional part using the detection signal to perform a predetermined function, wherein the MI sensor has the above-mentioned structure according to the present invention. The electronic equipment may be a portable telephone which can detect and display a present location of the portable telephone.

Other objects, features and advantages of the present invention will become more apparent from the following detailed description when read in conjunction with the accompanying drawings.

### BRIEF DESCRIPTION OF THE DRAWINGS

FIG. 1 is a perspective view of an MI sensor according to an embodiment of the present invention;

FIG. 2 is a perspective view of an MI element;

FIGS. 3A through 3D are illustrations for explaining the principle of the MI element;

FIG. 4 is a circuit diagram of an IC chip for the MI sensor shown in FIG. 1;

FIG. 5 is a waveform chart of signals and operations of the IC chip;

FIG. 6 is a plan view showing a circuit arrangement of the IC chip and the MI elements; and

FIG. 7 is a plan view of a portable telephone equipped with an MI sensor according to the present invention.

### DETAILED DESCRIPTION OF THE PREFERRED EMBODIMENTS

A description will now be given of an embodiment of the present invention.

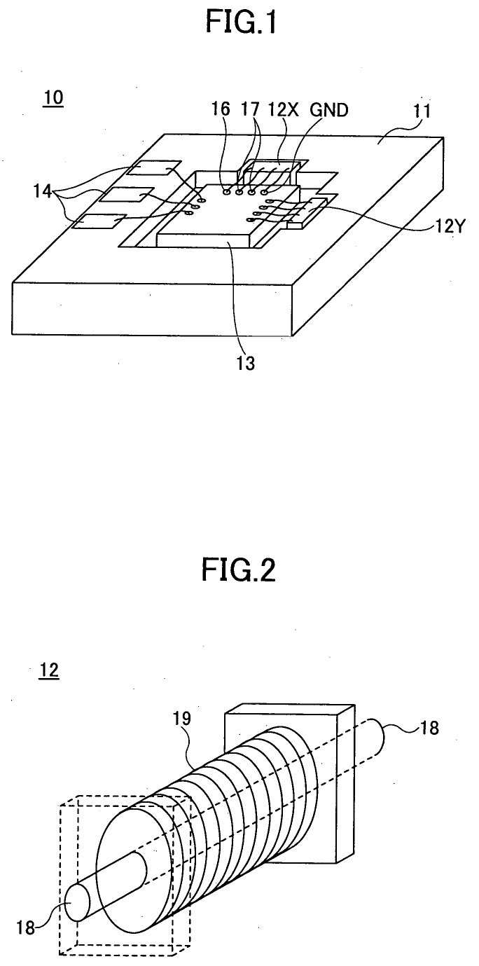

FIG. 1 is a perspective view of an MI sensor according to the embodiment of the present invention. With reference to FIG. 1, the MI sensor 10 according to the present invention comprises: a case 11 made of ceramics, glass, plastics or silicon; two magnetic impedance elements 12X and 12Y (hereinafter referred to as MI elements) provided in the case 11 and perpendicular to each other (X-axis and Y-axis) in the same plane; and an IC chip 13 provided in the case 11 and connected to the MI elements 12x and 12Y. In the MI sensor 10, a magnetizing current is supplied to each of the MI elements 12X and 12Y from the IC chip 13 so that a sense signal corresponding to the magnitude of an external magnetic field is induced by a magnetic impedance effect in each of the MI elements 12X and 12Y of X-axis and Y-axis. The IC chip 13 processes the detected signals and outputs an output signal corresponding to the magnitude of the external magnetic field so as to detect the magnitude and the direction of the external magnetic field.

The case 11 is provided with a square recessed part which accommodates the IC chip 13, and also provided with two recessed parts which accommodate the MI elements 12X and 12Y, respectively. Each of the two recessed parts for the MI elements has a length of about 4 mm and a width of several millimeters. Additionally case electrodes 14 are provided in a peripheral part of the upper surface of the case 11 so that the case electrodes 14 are connected by wires 15 to the IC chip 13 and terminals through which signals are exchanged with an external part.

The IC chip 13 is constituted by a CMOS or bipolar IC having a circuit mentioned later. The IC chip 13 is provided with an external device (not shown) such as a microprocessor, etc. on the surface thereof, and also provided on the surface are magnetizing current electrodes 16 and sense signal electrodes 17 that are connected to the MI elements 12X and 12Y. The IC chip 13 supplies a pulsed magnetizing current to amorphous wires (shown in FIG. 2) of the MI elements 12X and 12Y through the magnetizing current electrodes 16. The IC chip 13 is supplied with sense signals corresponding to the magnitude of the external magnetic field through the sense signal electrodes 17 so that a detection signal corresponding to the external magnetic field is produced and output by a circuit mentioned later.

The two MI elements 12X and 12Y are accommodated in the case 11 perpendicular to each other so as to detect magnitude of components of the external magnetic field in two axes. Each of the MI elements 12X and 12Y has a length of 4 mm, a width of about 1 mm and a height of about 0.3 mm, for example.

FIG. 2 is a perspective view of the MI element 12, which corresponds to each of the MI elements 12X and 12Y. The MI element 12 comprises an amorphous wire 18 formed of a soft magnetic material, such as NiFe, CoFeB, etc., which has no magnetic distortion and a sense coil 19 wound on the amorphous wire 18. The MI element 12 can detect the direction and magnitude of an external magnetic field according to the magnetic impedance effect.

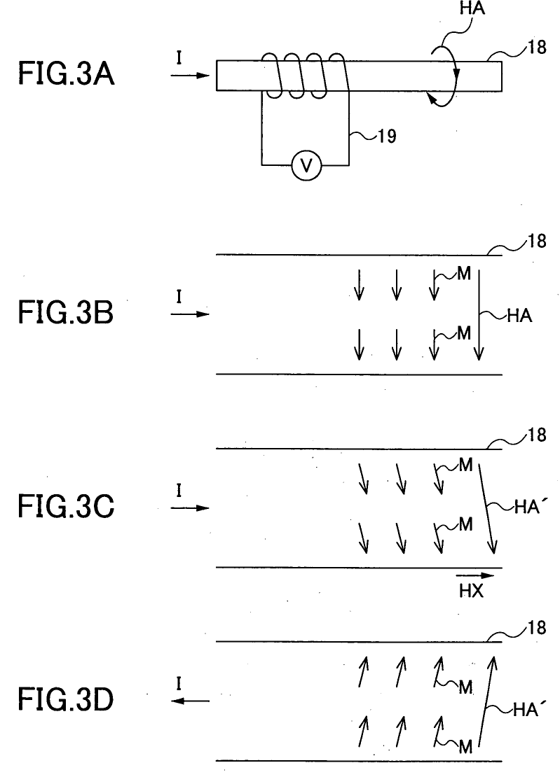

A description will now be given of a principle of detection of a magnetic field of the MI element 12. FIGS. 3A through 3D are illustrations for explaining the principle of the MI element. With reference to FIG. 3A, a magnetizing current I is supplied to the amorphous wire 18 so as to generate a magnetic field HA around the amorphous wire 18 by the magnetizing current I. The amorphous wire 18 has magnetization M since the amorphous wire 18 is a ferromagnetic material having a soft magnetic property. The magnetization M is arranged in a circumferential direction of the amorphous wire 18 due to the magnetic field HA as shown in FIG. 3B. When the magnetizing current I is an alternate current, the direction of magnetization M switches periodically at the same frequency as the alternate current. If an external magnetic field Hx is applied to the amorphous wire 18 in a longitudinal direction thereof, a synthetic magnetic field HA′, which is a combination of the magnetic filed HA and the external magnetic field Hx, is applied to the magnetization M of the amorphous wire 18, which results in a change in the direction of the magnetization M as shown in FIG. 3C and 3D. Then, the magnetic field along the longitudinal direction of the amorphous wire 18 is changed periodically. Thus, a sense signal proportional to the magnetic field Hx is induced in the sense coil 19 wound on the amorphous wire 18 as shown in FIG. 3A, and the magnitude of the magnetic field can be detected based on the sense signal. Further, by arranging another MI element perpendicularly to the MI element 12 like the MI elements 12X and 12Y as shown in FIG. 1, a magnetic field component in the perpendicular direction can be detected. Thus, the magnitude and the direction of a magnetic field can be detected by two MI elements, such as MI elements 12X and 12Y shown in FIG. 1, that are arranged perpendicular to each other.

It should be noted that a peak value of the voltage signal induced in the sense coil 19 is proportional to the frequency of the magnetizing current.

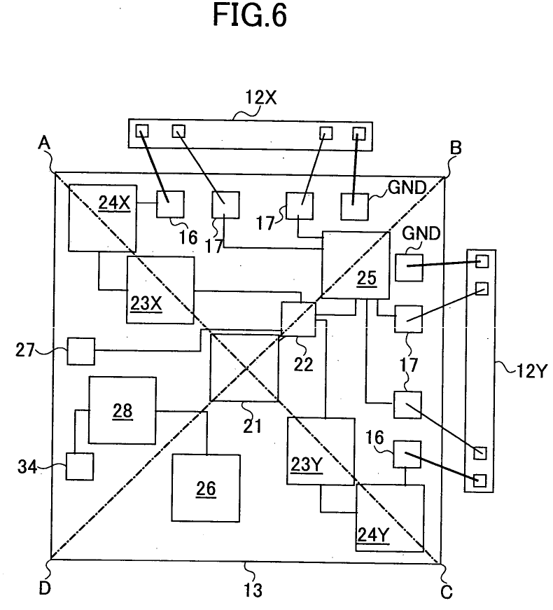

Therefore, when the magnetizing current I is pulsed a high-frequency component contained in the magnetizing current I changes according to a degree of steepness of the rising of the pulse. If the rising of the magnetizing current I supplied to each of the MI elements 12X and 12Y differs from each other, the peak values of the sense signals induced in the sense coils 19X and 19Y differ from each other even if magnetic fields of the same magnitude are applied to the sense coils 19A and 19Y. Therefore, if the current waveforms, especially the rising waveforms, of the magnetizing currents supplied to the respective MI elements 12X and 12Y are set equal to each other, a difference in sensitivity of the MI elements 12X and 12Y of two axes by a circuit arrangement of the present invention explained with reference to FIG. 6.

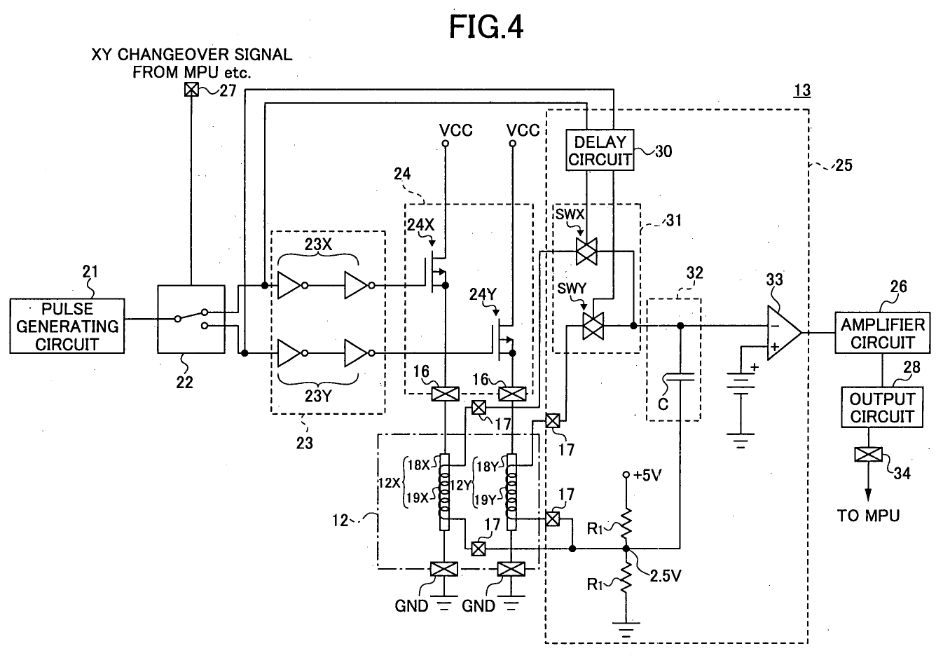

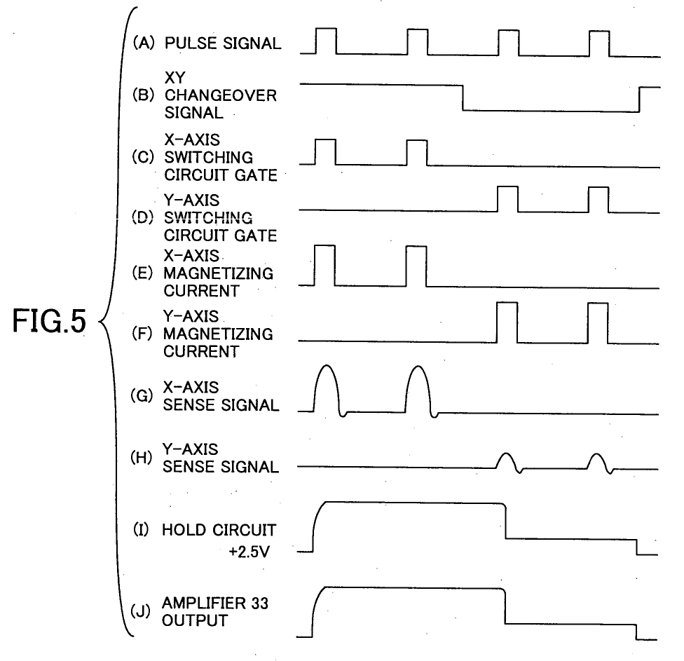

A description will now be given, with reference to FIG. 4 and FIG. 5, of the IC chip for the MI sensor according to the embodiment of the present invention.

FIG. 4 is a circuit diagram of the IC chip for the MI sensor according to the present embodiment. FIG. 5 is a waveform chart of signals and operations of the IC chip.

Referring to FIG. 4, the IC chip 13 according to the present embodiment comprises a pulse generating circuit 21, an XY-axis changeover switch 22, a buffer circuit 23 consisting of buffer circuits 23X and 23Y, a switching circuit 24 consisting of switching circuits 24X and 24Y, a detection circuit 25, an amplifier circuit 26 and an output circuit 28.

Hereinafter, the MI elements 12X and 12Y together may be generally referred to as MI element 12. Similarly, the buffer circuits 23X and 23Y together may be generally referred to as a buffer circuit 23, and the switching circuits 24X and 24Y together may be generally referred to as a switching circuit 24.

The buffer circuit 23 and the switching circuit 24 that are circuit portions for supplying the magnetizing current to the MI element 12 are provided independently for each of the X-axis and the Y-axis, and other circuit portions are provided commonly to the X-axis and the Y-axis. The independent circuit portions supply a sufficient magnetizing current to the respective MI elements 12X and 12Y arranged separately from each other so as to avoid an increase in crosstalk noise due to interference of signals for the X-axis and the Y-axis. Additionally, the common circuit portions such as the pulse generating circuit 21 and the detection circuit 25 commonly generate or process signals for the X-axis and the Y-axis so as to reduce a difference in sensitivity between the X-axis and the Y-axis. Further, since the number of circuits is reduced, the miniaturization of the IC chip can be achieved. A description will be given below of each circuits provided in the IC chip 13.

In the pulse generating circuit 21, a high-frequency or pulsed signal of the frequency of 200 kHz to ten and several MHz is generated. Specifically, a pulse signal of a duty ratio of about 50% is generated by an oscillating circuit using a multi-vibrator or a crystal oscillator. The pulse signal is delayed by an integration circuit so as to perform an AND operation on the original signal and the delayed signal so as to generate pluses having a very short time width of, for example, 1 to 30 nsec. In the present embodiment, the period of the pulses is set to 500 kHz.

The pulse signal generated by the pulse generating circuit 21 is supplied to the XY-axis changeover switch 22, and the pulse signal is distributed to the X-axis and the Y-axis. Specifically, the XY-axis changeover switch 22 is controlled by an XY-axis changeover signal supplied through an XY-axis changeover signal electrode 27 so as to distribute the pulse signal to the buffer circuit 23X of the X-axis and the buffer circuit 23Y of the Y-axis. It should be noted that the XY-axis changeover signal is a digital signal of “L” or “H” as shown in FIG. 5-(B) which is supplied from, for example, an MPU or the like provided in an electronic device which is equipped with the MI sensor 10. For example, when the XY-axis changeover signal is “H”, the pulse signal is distributed to the buffer circuit 23X of the X-axis, and when the XY-axis changeover signal is “L”, the pulse signal is distributed to the buffer circuit 23Y of the Y-axis.

The buffer circuit 23 is constituted by several buffers to ten and several buffers. For example, a product of a gate width and a gate length of CMOS-FETs may be gradually increased so that a larger drive current can be supplied to a buffer circuit located at further downstream side. A large current can be supplied by control parts of the switching circuits 24X and 24Y. Moreover, as shown in FIG. 5-(C) and (D), a pulse signal is supplied alternately to the buffer circuits 23X and 23Y of the X-axis and the Y-axis.

In the switching circuits 24X and 24Y, the pulse signal of which current is amplified by the buffer circuits 23X and 23Y, respectively, is supplied to the control part. The switching circuits 24X and 24Y are constituted by a MOS-FET, and the pulse signal is input into the gate thereof. When the MOS-FET is turned on by the pulse signal, a magnetizing current is supplied through the electrodes to the MI elements 12X and 12Y connected to the electrodes. The magnetizing current is preferably 100 mA to 500 mA. If the magnetizing current is smaller than 100 mA, a sufficient current cannot be induced in the sense coils 19X and 19Y of the MI elements 12X and 12Y, which results in degradation of the signal-to-noise ratio. On the other hand, if the magnetizing current is larger than 500 mA, there may occur an erroneous operation such that one of the switching circuits 24X and 24Y which must be off is turned on due to a crosstalk between the switching circuits 24X and 24Y. Moreover, in order to avoid a crosstalk, it is preferable that the switching circuits 24X and 24Y of the X-axis and the Y-axes are located away from each other, and it is still more preferable that they are located on opposite ends of a diagonal line of the IC chip 13.

The magnetizing current from the switching circuit 24 is supplied to the magnetizing current electrodes 16 (shown in FIG. 1) formed on the surface of the IC chip 13. It is preferable that the magnetizing current electrodes 16 are located near the switching circuit 24 and the MI element 12 as close as possible. For example, the magnetic current electrodes 16 are located near the sides of the IC chip 13 facing the MI elements 12X and 12Y. Since the magnetizing current is a relatively large current, if the wiring from the switching circuit 24 to the MI element 12 is too long, the wiring may serve as an antenna, which emits electromagnetic waves, thereby reducing a signal-to-noise ratio.

A pulsed magnetizing current flows through the amorphous wire 18 of each of the MI elements 12X and 12Y that are connected to the magnetizing current electrodes 16 by wires, and flows to grounding terminals GND of the IC chip 13. Sense signals are induced in the sense coil 19 as shown in FIG. 5-(G) and (H), in response to a magnitude of a component of the external magnetic field parallel to the amorphous wire 18. This sense signals are supplied to the detection circuit 25 through the wires and sense signal electrodes 17 formed on the surface of the IC chip 13. It should be noted that the magnetizing current may flow to the grounding terminals of the MI sensor instead of the grounding terminals GND of the IC chip 13.

The detection circuit 25 comprises a delay circuit 30, a sampling circuit 31, a hold circuit 32, an amplifier 33, etc. In the detection circuit 25, main peaks of Lie sense signals induced in the detection coils 19X and 19Y of the X-axis and the Y-axis are sampled by the sampling circuit 31 which is synchronized with a pulse signal, and the peak values are held by the hold circuit 32.

The sampling circuit 31 comprises analog switches SWX and SWY. That is, as shown in FIG. 5-(G) and (H), the pulse signal shown in FIG. 5-(C) and (D) is supplied to the control section of the analog switches SWX and SWY with respect to the sense signal of the detection coils 19X and 19Y, and the sense signal is passed through when the pulse signal is “H”. Since a delay relative to the pulse signal has been provided to the sense signal by the buffer circuit 23 and the switching circuit 24, the pulse signal is delayed by a delay circuit (not shown in the figure) so as to be synchronized with the rising of the sense signal. According to the above-mentioned structure, the main peak of the sense signal can be passed through.

In the detection circuit 25, as shown in FIG. 5-(I), the time series sense signals of the X-axis and the Y-axis are held by the hold circuit 23 which is constituted by a capacitor, etc. Subsequently, the amplifier 33 amplifies the held signal and outputs as a detection signal.

The amplifier circuit 26 amplifies the detection signal to a predetermined voltage, and outputs the amplified detection signal to an external device of the IC chip 13 through the output electrode 34 provided on the surface of the IC chip 13. In the present embodiment, the output circuit 28 is provided behind the amplifier circuit 26 so as to convert the signal output from the amplifier circuit 26 into a low-impedance output signal. The outputs signal may be converted into a digital signal by an A/D converter. It should be noted that, in the electronic apparatus equipped with the MI sensor 10, a magnitude and a direction of an external magnetic field can be obtained by extracting and synthesizing magnetic field components of the X-axis and the Y-axis from the output signal of the IC chip 13 by using the above-mentioned XY-axis changeover signal.

A description will now be given of an arrangement of the circuits constituting the IC chip 13.

FIG. 6 is a plan view showing the circuit arrangement of the IC chip and the MI elements.

Referring to FIG. 6, the MI elements 12X and 12Y of the X-axis and the Y-axis are located along adjacent sides of the IC chip 13, respectively.

The pulse circuit 21 is arranged on a first diagonal line (indicated by a single dashed chain line B-D extending between the two sides facing the MT elements 12X and 12Y. Since the pulse circuit 21 is connected to the circuits of both the X-axis and the Y-axis and also connected to both the MI elements 12X and 12Y, the lengths of the wirings for the circuits of the X-axis and the Y-axis can be equalized by locating the pulse circuit 21 at a position symmetric to the MI elements 12X and 12Y. Accordingly, distortion of the waveforms of the pulse signals due to parasitic capacitance and parasitic inductance of the circuits can be equalized, thereby equalizing the degree of influence to the output signals. Additionally, since the pulse circuit 21 is located at the same distance or almost the same distance from both the switching circuits 24X and 24Y of the X-axis and the Y-axis, the wiring lengths from the pulse circuit 21 to both the switching circuits 24X and 2Y can be equalized. It should be noted that the pulse circuit 21 be located in the same manner relative to the magnetizing current electrodes 16.

The buffer circuits 23X and 23Y are located at almost symmetric positions with respect to the pulse circuit 21 so as to equalize the wiring lengths from the pulse circuit 21 to both the buffer circuits 23X and 23Y. Additionally, the buffers constituting the buffer circuits 23X ands 23Y have the same structure. Operational speeds of the buffers are equalized by equalizing the design rules such as the gate lengths of the buffers so that the timing of the pulse signal and the timing of the detection signal do not differ between the X-axis and the Y-axis.

The switching circuits 24X and 24Y are located distant from each other. For example, the switching circuits 24X and 24Y are preferably located at positions near ends of the two sides of the IC chip 13 that face the respective MI elements 12X and 12Y opposite to the ends at which the two sides intersects with each other, or preferably located on or near the second diagonal line (indicated by a single dashed chain line A-C) connecting the ends of the two sides opposite to the ends at which the two sides intersects with each other. According to the above-mentioned arrangement of the switching circuits 24X and 24Y, generation of crosstalk of the switching circuits 24X and 24Y can be suppressed.

The switching circuits 24X and 24Y are located near the respective magnetizing current electrodes 16 which supply a magnetizing current to the MI elements 12X and 12Y. The wiring lengths from the switching circuits 24X and 24Y to the respective magnetizing current electrodes 16 are reduced as short as possible so as to reduce emission of electromagnetic waves from the wiring. Further, the positional relationship between the switching circuit 24X and the MI elements 12X is the same as that of the switching circuit 24Y and the MI element 12Y. For example, the distance between the switching circuit 24X and the MI element 12X is set equal to the distance between the switching circuit 24Y and the MI element 12Y. Accordingly, a parasitic resistance, a parasitic capacitance and a parasitic inductance are equalized between the X-axis and the Y-axis so as to equalize the distortion of the waveforms of the pulsed magnetizing currents, and generation of a difference in timing between the sampling circuits of the X-axis and the Y-axis can be prevented.

The magnetizing current electrodes 16 which are formed on the surface of the IC chip 13 for supplying the magnetizing current to the MI elements 12X and 12Y are located at or near the sides facing the MI elements 12X and 12Y, respectively. The wiring lengths from the magnetizing current electrodes 16 to the respective MI elements 12X and 12Y are set as short as possible so as to reduce emission of electromagnetic waves from the wiring. The positional relationship between the switching circuit 24X and the corresponding magnetizing current electrode 16 and the positional relationship between the MI element 12X and the corresponding magnetizing electrode 16 are the same as the positional relationship between the switching circuit 24Y and the corresponding magnetizing electrode 16 and the positional relationship between the MI element 12Y and the magnetizing current electrode 16, respectively. Accordingly, a parasitic resistance, a parasitic capacitance and a parasitic inductance are equalized between the X-axis and the Y-axis so as to equalize the distortion of the waveforms of the pulsed magnetizing currents, and generation of a difference in timing between the sampling circuits of the X-axis and the Y-axis can be prevented.

The detection circuit 25 is located near the intersection of two sides facing the MI elements 12X and 12Y so as to prevent noises from being superimposed on the output signals of the MI elements 12X and 12Y. Especially, the detection circuit 25 is located at the equal distance from both the switching circuits 24X and 24Y. The influence of electromagnetic waves emitted from the switching circuits 24X and 24Y is reduced, and the influence can be equalized between the X-axis and the Y-axis.

The amplifier circuit 26 and the output circuit 28 are located at positions opposite to the two sides facing the MI elements 12X and 12Y with respect to the second diagonal line. Accordingly noises from the switching circuit 24 are prevented from being superimposed on the signal of the signal of the amplifier circuit 26 and the output circuit 28. Moreover, the output electrode 34 for outputting the signal is located in the same manner.

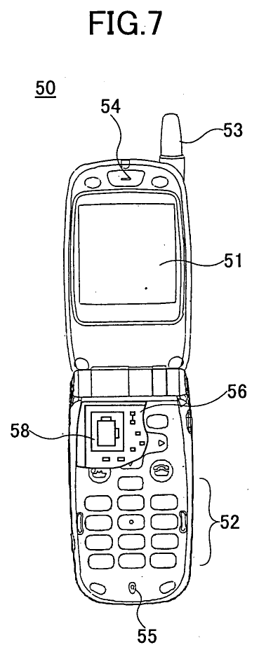

FIG. 7 is a plan view of a portable telephone equipped with an MI sensor according to the present invention. As shown in FIG. 7, the portable telephone 50 comprises a display part 51, an operational part 52, an antenna 53, a speaker 54, a microphone 55, a communication board 56 and an MI sensor 58 mounted on the communication board 56.

The MI sensor 58 has the same structure as the MI sensor 10 according to the above-mentioned embodiment. It is possible to detect by the MI sensor 58 an angle of direction at which the portable telephone 50 is oriented based on the direction of the earth magnetism. For example, a map indicating the present position which the portable telephone received and displays on the display part 51 can be rotated on the display part 51 in accordance with the angle of direction of the portable telephone 50 detected by the MI sensor 58 so that the map is easily viewable.

As mentioned above, the MI sensor 58 of the present invention detects an external magnetic field by driving the MI element 12 by the IC chip. Therefore, the MI sensor 58 can be more miniaturized than a magnetic sensor constituted by conventional discrete circuits. It should be noted that the basic structure of the portable telephone 50 is well-known, and descriptions there of will be omitted.

Although the MI sensor having the two-axes MI elements is explained as an example in the above-mentioned embodiment of the present invention, the present invention may be applicable to an MI element having a one-axis MI element. In such an MI sensor, a single MI element 12 located near one side of the IC chip 13, and the positional relationship between the MI element and the magnetizing current electrode 16 or the positional relationship between the MI element 12 and the switching circuit 24 is set in the same manner as the above-mentioned embodiment. Additionally, the switching circuit may be constituted by a bipolar transistor, etc.

The present invention is not limited to the specifically disclosed embodiments, and variations and modifications may be made without departing from the scope of the present invention.

The present invention is based on Japanese priority application No. 2002-278175 filed Sep. 24, 2003, the entire contents of which are hereby incorporated by reference.

What is claimed is:

1. An IC chip configured and arranged to be used with an MI sensor which detects an external magnetic field and outputs a sense signal, the IC chip having a rectangular shape and supplied with the sense signal output from the MI element, said IC chip comprising:
an MI element connection electrode connected to said MI element; and
a switching circuit controlled by a pulse signal so as to supply a pulsed magnetizing current to said MI element through the MI element connection electrode,
wherein said MI element connection electrode is located near a side of said IC chip.

2. The IC chip as claimed in claim 1, wherein said switching circuit is located near the side to which said MI element is located.

3. An IC-chip configured and arranged to be used with MI elements including first and second MI elements, the IC chip having a rectangular shape and supplied with a sense signal from each of the first and second MI elements, said IC chip comprising:
a first MI element connection electrode connected to said first MI element;
a second MI element connection electrode connected to said second MI element;
a first switching circuit supplying a magnetizing current to said first MI element through the first MI element connection electrode; and
a second switching circuit supplying a magnetizing current to said second MI element through said second MI element,
wherein said first and second switching circuits are separated from each other and located symmetrically with respect to a first diagonal line of the rectangular IC chip, the first diagonal line extending between said first and second MI elements.

4. The IC chip as claimed in claim 3, wherein said first and second switching circuits are located on a second diagonal line different from said first diagonal line.

5. The IC chip as claimed in claim 3, further comprising first and second pulse-signal generation circuits which generate pulse signals for controlling said first and second switching circuits, respectively, wherein said pulse-signal generation circuits are located at equal distances from the respective first and second switching circuits.

6. The IC chip as claimed in claim 5, further comprising a signal processing circuit which generates a detection signal corresponding to a magnitude of the external magnetic field by being supplied with the sense signals from said first and second MI elements, wherein said signal processing circuit includes a sampling circuit and located at equal distances from said first and second switching circuits.

7. The IC chip as claimed in claim 6, wherein an operational timing of said sampling circuit and an operational timing of said first and second switching circuits are synchronized with each other.

8. The IC chip as claimed in claim 6, further comprising an MI element changeover switch which switches a direction of the magnetizing current between said first and second MI elements based on a switching signal supplied from an external part, wherein said pulse-signal generation circuit are commonly used for said first and second MI elements.

9. The IC chip as claimed in claim 6, further comprising an amplifier circuit amplifying the detection signal output from said signal processing circuit, wherein said amplifier circuit is located at a position opposite to said first and second MI element connection electrodes with respect to said second diagonal line.

10. The IC chip as claimed in claim 9, further comprising an output circuit which outputs the amplified detection signal supplied from said amplifier circuit, wherein said output circuit is located at a position opposite to said first and second MI element connection electrodes with respect to said second diagonal line.

11. The IC chip as claimed in claim 10, further comprising an output electrode which outputs the detection signal supplied from said output circuit to an external part, wherein said output electrode is located at a position opposite to said first and second MI element connection electrodes with respect to said second diagonal line.

12. An MI sensor comprising:
an MI element detecting an external magnetic field and outputting a sense signal; and
an IC chip having a rectangular shape and supplied with the sense signal output from said MI element,
wherein said IC chip comprises:
an MI element connection electrode connected to said MI element; and
a switching circuit controlled by a pulse signal so as to supply a pulsed magnetizing current to said MI element through the MI element connection electrode,
wherein said MI element connection electrode is located near a side of said IC chip.

13. The MI sensor as claimed in claim 12, wherein said switching circuit is located near the side to which said MI element is located.

14. An MI sensor comprising:
a first MI element detecting an external magnetic field and outputting a sense signal;
a second MI element detecting an external magnetic field and outputting a sense signal, the second MI element being positioned at a predetermined angle to said first MI element; and
an IC chip having a rectangular shape and supplied with the sense signals from the first and second MI elements,
wherein said IC chip comprising:
a first MI element connection electrode connected to said first MI element;
a second MI element connection electrode connected to said second MI element;
a first switching circuit supplying a magnetizing current to said first MI element through the first MI element connection electrode; and
a second switching circuit supplying a magnetizing current to said second MI element through said second MI element connection electrode,
wherein said first and second MI elements face adjacent sides of said IC chip, respectively; and
said first and second switching circuits are located at identical positions with respect to the respective first and second MI elements.

15. The MI sensor as claimed in claim 14, wherein said first and second switching circuits are located on a second diagonal line different from a first diagonal extending between the adjacent sides facing the first and second MI elements, respectively.

16. The MI sensor as claimed in claim 14, further comprising first and second pulse-signal generation circuits which generate pulse signals for controlling said first and second switching circuits, respectively, wherein said pulse-signal generation circuits are located at equal distances from the respective first and second switching circuits.

17. The MI sensor as claimed in claim 14, further comprising a signal processing circuit which generates a detection signal corresponding to a magnitude of the external magnetic field by being supplied with the sense signals from said first and second MI elements, wherein said signal processing circuit includes a sampling circuit and located at equal distances from said first and second switching circuits.

18. The MI sensor as claimed in claim 17, wherein an operational timing of said sampling circuit and an operational timing of said first and second switching circuits are synchronized with each other.

19. The MI sensor as claimed in claim 17, further comprising an MI element changeover switch which switches a direction of the magnetizing current between said first and second MI elements based on a switching signal supplied from an external part, wherein said pulse-signal generation circuit and said signal processing circuit are commonly used for said first and second MI elements.

20. The MI sensor as claimed in claim 17, further comprising an amplifier circuit amplifying the detection signal output from said signal processing circuit, wherein said amplifier circuit is located at a position opposite to said first and second MI element connection electrodes with respect to a second diagonal line different from a first diagonal line extending between the adjacent sides facing the first and second MI elements, respectively.

21. The MI sensor as claimed in claim 20, further comprising an output circuit which outputs the amplified detection signal supplied from said amplifier circuit, wherein said output circuit is located at a position opposite to said first and second MI element connection electrodes with respect to said second diagonal line.

22. The MI sensor as claimed in claim 21, further comprising an output electrode which outputs the detection signal supplied from said output circuit to an external part, wherein said output electrode is located at a position opposite to said first and second MI element connection electrodes with respect to said second diagonal line.

23. An electronic equipment comprising:
an MI sensor detecting an external magnetic field and outputting a detection signal; and
a functional part using the detection signal to perform a predetermined function,
wherein said MI sensor comprising:
an MI element detecting the external magnetic field and outputting a sense signal; and
an IC chip having a rectangular shape and supplied with the sense signal output from said MI element so as to output the detection signal,
wherein said IC chip comprises:
an MI element connection electrode connected to said MI element; and
a switching circuit controlled by a pulse signal so as to supply a pulsed magnetizing current to said MI element through the MI element connection electrode,
wherein said MI element connection electrode is located near a side of said IC chip.

24. The electronic equipment as claimed in claim 23, wherein said switching circuit is located near the side to which said MI element is located.

25. An electronic equipment comprising:
an MI sensor detecting an external magnetic field and outputting a detection signal; and
a functional part using the detection signal to perform a predetermined function,
wherein said MI sensor comprising:
a first MI element detecting the external magnetic field and outputting a sense signal;
a second MI element detecting the external magnetic field and outputting a sense signal, the second MI element being positioned at a predetermined angle to said first MI element; and
an IC chip having a rectangular shape and supplied with the sense signals from the first and second MI elements so as to output the detection signal,
wherein said IC chip comprising:
a first MI element connection electrode connected to said first MI element;
a second MI element connection electrode connected to said second MI element;
a first switching circuit supplying a magnetizing current to said first MI element through the first MI element connection electrode; and
a second switching circuit supplying a magnetizing current to said second MI element through said second MI element connection electrode,
wherein said first and second MI elements face adjacent sides of said IC chip, respectively; and
said first and second switching circuits are located at identical positions with respect to the respective first and second MI elements.

26. The electronic equipment as claimed in claim 25, wherein said first and second switching circuits are located on a second diagonal line different from a first diagonal extending between the adjacent sides facing the first and second MI elements, respectively.

27. The electronic equipment as claimed in claim 25, further comprising first and second pulse-signal generation circuits which generate pulse signals for controlling said first and second switching circuits, respectively, wherein said pulse-signal generation circuits are located at equal distances from the respective first and second switching circuits.

28. The electronic equipment as claimed in claim 25, further comprising a signal processing circuit which generates a detection signal corresponding to a magnitude of the external magnetic field by being supplied with the sense signals from said first and second MI elements, wherein said signal processing circuit includes a sampling circuit and located at equal distances from said first and second switching circuits.

29. The electronic equipment as claimed in claim 28, wherein an operational timing of said sampling circuit and an operational timing of said first and second switching circuits are synchronized with each other.

30. The electronic equipment as claimed in claim 28, further comprising an MI element changeover switch which switches a direction of the magnetizing current between said first and second MI elements based on a switching signal supplied from an external part, wherein said pulse-signal generation circuit and said signal processing circuit are commonly used for said first and second MI elements.

31. The electronic equipment as claimed in claim 28, further comprising an amplifier circuit amplifying the detection signal output from said signal processing circuit, wherein said amplifier circuit is located at a position opposite to said first and second MI element connection electrodes with respect to a second diagonal line different from a first diagonal line extending between the adjacent sides facing the first and second MI elements, respectively.

32. The electronic equipment as claimed in claim 31, further comprising an output circuit which outputs the amplified detection signal supplied from said amplifier circuit, wherein said output circuit is located at a position opposite to said first and second MI element connection electrodes with respect to said second diagonal line.

33. The electronic equipment as claimed in claim 32, further comprising an output electrode which outputs the detection signal supplied from said output circuit to an external part, wherein said output electrode is located at a position opposite to said first and second MI element connection electrodes with respect to said second diagonal line.
